(19) United States
(12) Patent Application Publication
(10) Pub. No.: US 2026/0056247 A1
(43) Pub. Date: Feb. 26, 2026

(54) POSITIONING TYPE WAFER INSPECTION DEVICE

(71) Applicant: CHROMA ATE INC., TAOYUAN CITY (TW)

(72) Inventors: Wen-Chung WANG, TAOYUAN CITY (TW); Ching-Lin LEE, TAOYUAN CITY (TW)

(21) Appl. No.: 19/215,521

(22) Filed: May 22, 2025

(30) Foreign Application Priority Data
Aug. 23, 2024 (TW) 113131897

(51) Int. Cl. G01R 31/28

(52) U.S. Cl. CPC G01R 31/2831

(57) ABSTRACT

A positioning type wafer inspection device includes a wafer fixing platform, a horizontal moving base, a probe module, a die position holder, and a detection parameter acquisition module. The wafer fixing platform features a positioning structure designed to keep a wafer within a detection position range and expose the wafer through an opening. The horizontal moving base is used to move the wafer fixing platform on a horizontal plane. The probe module is movably positioned on one side of the wafer along a contact direction. The die position holder is movably positioned on the opposite side of the wafer along a stopping direction. The detection parameter acquisition module is positioned on the side of the wafer opposite the probe module to acquire optical detection parameters.

This application claims the benefit of Taiwan Patent Application Serial No.113131897, filed on Aug. 23, 2024, the subject matter of which is incorporated herein by reference.

### BACKGROUND OF THE INVENTION

### (1) Field of the Invention

The invention relates to a wafer inspection device, and more particularly to a positioning type wafer inspection device.

### (2) Description of the Prior Art

In general, when inspecting multiple flip chip dies on a wafer, the wafer is usually placed on a transparent carrier with the electrode portion of the flip chip dies facing upward and the light-emitting portion facing downward. Then, a probe is extended from the top of the wafer toward the wafer to contact the electrode portion of the flip chip dies to be detected and energize it, so that the light signal generated by the light-emitting portion of the flip chip dies to be detected penetrates the transparent carrier below and is then received by the receiving device below.

However, when the light signal generated by the light-emitting portion penetrates the transparent carrier below, the light signal is often refracted, scattered or absorbed due to the transparent carrier, resulting in distortion of the signal received by the receiving device.

### SUMMARY OF THE INVENTION

The main purpose of the present invention is to provide a positioning type wafer inspection device, which can effectively stabilize the wafer during inspection without using a transparent carrier to support and stabilize the wafer.

To solve the problems of the prior art, the necessary technical means adopted by the present invention is to provide a positioning type wafer inspection device, for inspecting a plurality of flip chip dies on a wafer, the wafer having a first surface and a second surface opposite to the first surface, each of the flip chip dies has an electrode portion on the first surface and a light-emitting portion electrically connected to the electrode portion on the second surface. The positioning type wafer inspection device includes a wafer fixing platform, a horizontal moving base, a probe module, a die position holder, and a detection parameter acquisition module.

The wafer fixing platform has a positioning structure which has an opening. The positioning structure is used to keep the wafer within a detection position range and expose the wafer through the opening.

The horizontal moving base is used to carry the wafer fixing platform and move the wafer fixing platform on a horizontal plane to move a to-be-detected die among the flip chip dies to a detection position.

The probe module is movably disposed on one side of the wafer along a contact direction perpendicular to the horizontal plane, and is used to electrically contact the electrode portion of the to-be-detected die along the contact direction.

The die position holder is movably disposed on the opposite side of the wafer relative to the probe module along a stopping direction opposite to the contact direction, and is used to apply a holding force to the wafer along the stopping direction, thereby when probe module contacts the to-be-detected die, the to-be-detected die is kept at the detection position.

The detection parameter acquisition module is disposed on the opposite side of the wafer relative to the probe module, and is used to acquire optical detection parameters from the light-emitting portion of the to-be-detected die when the probe module electrically contacts the to-be-detected die.

Among the ancillary technical means derived from the above necessary technical means, the die position holder has a through hole, when the die position holder applies the holding force against the wafer along the stopping direction, the to-be-detected die is exposed from the through hole, so that the detection parameter acquisition module acquires optical detection parameters from the light-emitting portion of the to-be-detected die via the through hole.

Preferably, the die position holder is a non-contact holder, and the die position holder is provided with a plurality of air pressure regulating holes around the through hole.

Among the ancillary technical means derived from the above necessary technical means, when the first surface of the wafer faces downward and is exposed from the opening, the probe module is disposed below the wafer, and the die position holder and the detection parameter acquisition module are disposed above the wafer.

Among the ancillary technical means derived from the above necessary technical means, when the second surface of the wafer faces downward and is exposed from the opening, the probe module is disposed above the wafer, and the die position holder and the detection parameter acquisition module are disposed below the wafer.

Among the ancillary technical means derived from the above necessary technical means, the wafer fixing platform includes a carrier plate and two side support seats, the carrier plate has the positioning structure, the two side support seats are respectively connected to the opposite sides of the carrier plate, and the horizontal moving base is used to hold the two side support seats.

Preferably, the horizontal moving base further includes a first moving component and a second moving component, the first moving component holds the two side support seats to drive the wafer fixing platform to reciprocate along a first horizontal direction, and the second moving component holds the first moving component to drive the first moving component and the wafer fixing platform to reciprocate along a second horizontal direction perpendicular to the first horizontal direction.

As mentioned above, since the positioning type wafer inspection device of the present invention utilizes a positioning structure with an opening to hold the wafer, the bottom of the wafer can be exposed from the opening, so that the probe module can contact the electrode portion of the wafer from the bottom or top of the wafer. The present invention also provides a die position holder on the other side of the wafer relative to the probe module, thereby stabilizing the wafer when the probe module contacts the wafer, thereby preventing the image captured by the detection parameter acquisition module from being disturbed and increasing the stability during inspection.

The specific embodiments used in the present invention will be further explained through the following embodiments and drawings.

### BRIEF DESCRIPTION OF THE DRAWINGS

The present invention will now be specified with reference to its preferred embodiment illustrated in the drawings, in which:

FIG. 1 is a schematic diagram showing a positioning type wafer inspection device provided by a preferred embodiment of the present invention;

FIG. 2 is a three-dimensional schematic diagram showing the wafer fixing platform and the horizontal moving base provided by a preferred embodiment of the present invention;

FIG. 3 is an enlarged schematic diagram of circle A in FIG. 1;

FIG. 4 is a schematic diagram showing the probe module and the die position holder contacting the wafer at the same time;

FIG. 5 is a schematic diagram of the details of the probe module and the die position holder contacting the wafer at the same time; and

FIG. 6 is a schematic diagram showing a positioning type wafer inspection device provided by another preferred embodiment of the present invention.

### DESCRIPTION OF THE PREFERRED EMBODIMENT

The invention disclosed herein is directed to a positioning type wafer inspection device. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

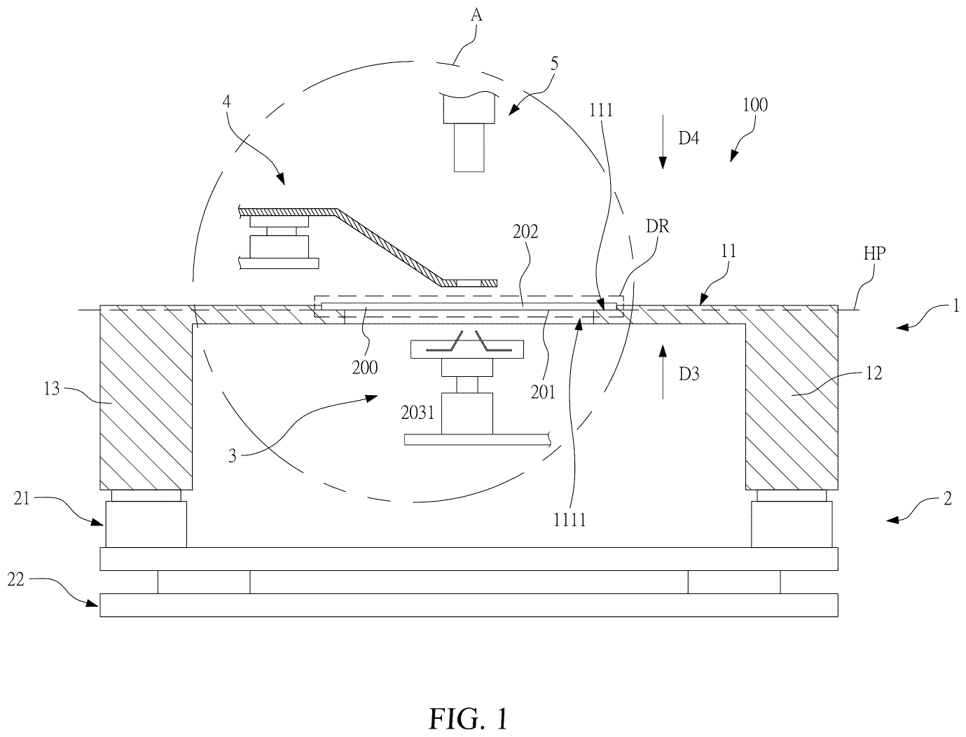

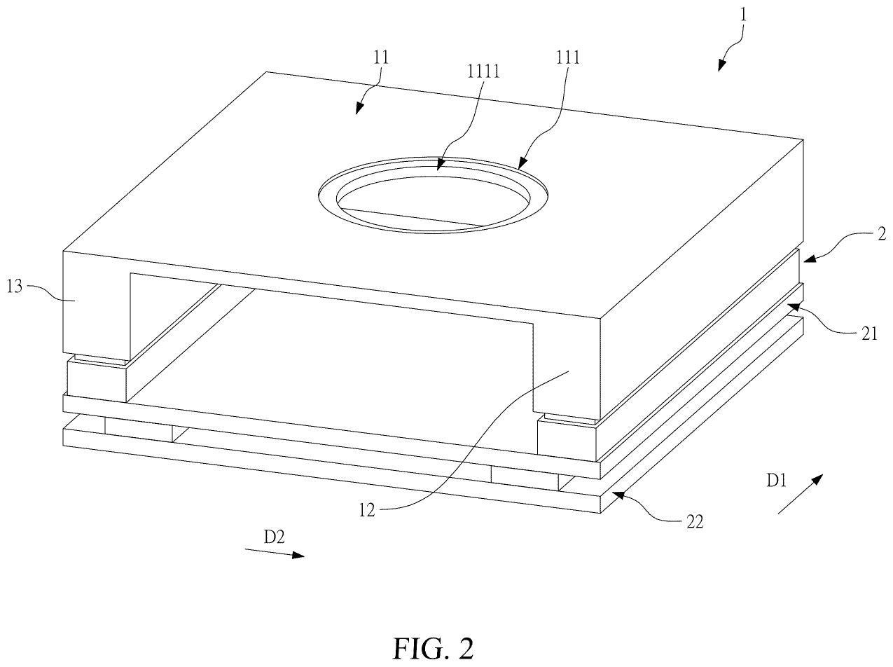

Referring to FIG. 1 and FIG. 2, FIG. 1 is a schematic diagram showing a positioning type wafer inspection device provided by a preferred embodiment of the present invention; FIG. 2 is a three-dimensional schematic diagram showing the wafer fixing platform and the horizontal moving base provided by a preferred embodiment of the present invention.

As shown in FIG. 1 and FIG. 2, a positioning type wafer inspection device 100 includes a wafer fixing platform 1, a horizontal moving base 2, a probe module 3, a die position holder 4, and a detection parameter acquisition module 5.

The wafer fixing platform 1 includes a carrier plate 11 and two side support seats 12, 13. The carrier plate 11 has a positioning structure 111, and the positioning structure 111 has an opening 1111, wherein the positioning structure 111 is used for placing a wafer 200, so as to keep the wafer 200 within a detection position range DR and expose the wafer 200 through the opening 1111. In addition, the positioning structure 111 is an annular groove in the present embodiment, and in practice, an air extraction hole may be provided to fix the periphery of the wafer 200 by negative pressure absorption. The opening 1111 is a circular opening in the present embodiment, but it is not limited thereto.

The two side support seats 12, 13 are respectively connected to two opposite sides of the bottom of the carrier plate 11 to form an arch-shaped structure.

The horizontal moving base 2 includes a first moving component 21 and a second moving component 22. The first moving component 21 holds the two side support seats 12, 13 to drive the wafer fixing platform 1 to reciprocate along a first horizontal direction D1. The second moving component 22 holds the first moving component 21 to drive the first moving component 21 and the wafer fixing platform 1 to reciprocate along a second horizontal direction D2 perpendicular to the first horizontal direction D1.

As mentioned above, by supporting the wafer fixing platform 1 on the horizontal moving base 2, the wafer fixing platform 1 can be effectively driven to move on a horizontal plane HP.

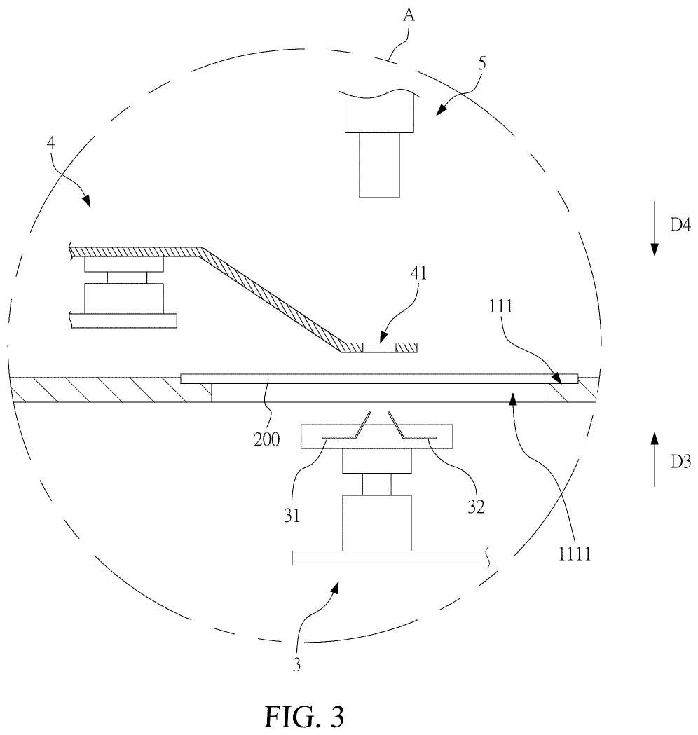

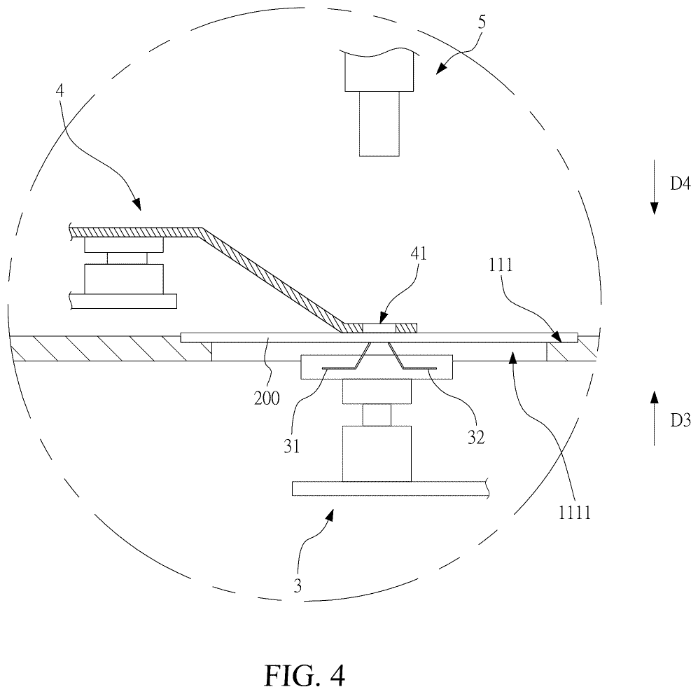

Referring now to FIG. 3 and FIG. 4, FIG. 3 is an enlarged schematic diagram of circle A in FIG. 1; FIG. 4 is a schematic diagram showing the probe module and the die position holder contacting the wafer at the same time. As shown in FIG. 1 to FIG. 4, the probe module 3 is movably disposed on one side of the wafer 200 along a contact direction D3 perpendicular to the horizontal plane HP, and the probe module 3 has two probes 31, 32.

The die position holder 4 is movably disposed on the opposite side of the wafer 200 relative to the probe module 3 along a stopping direction D4 opposite to the contact direction D3, and the die position holder 4 is used to apply a holding force to the wafer 200 along the stopping direction D4. The detection parameter acquisition module 5 is disposed on the opposite side of the wafer 200 relative to the probe module 3, that is, the detection parameter acquisition module 5 and the die position holder 4 are relative disposed on the same side of the wafer 200. The detection parameter acquisition module 5 is may be a device such as a camera or an integrating sphere for acquiring optical detection parameters.

As mentioned above, in the present embodiment, the die position holder 4 further includes a through hole 41, and the imaging axis of the detection parameter acquisition module 5 is aligned with the center of the through hole 41. The die position holder 4 applies the holding force against the wafer 200 so that the detection parameter acquisition module 5 can acquire optical detection parameters from the wafer 200 via the through hole 41.

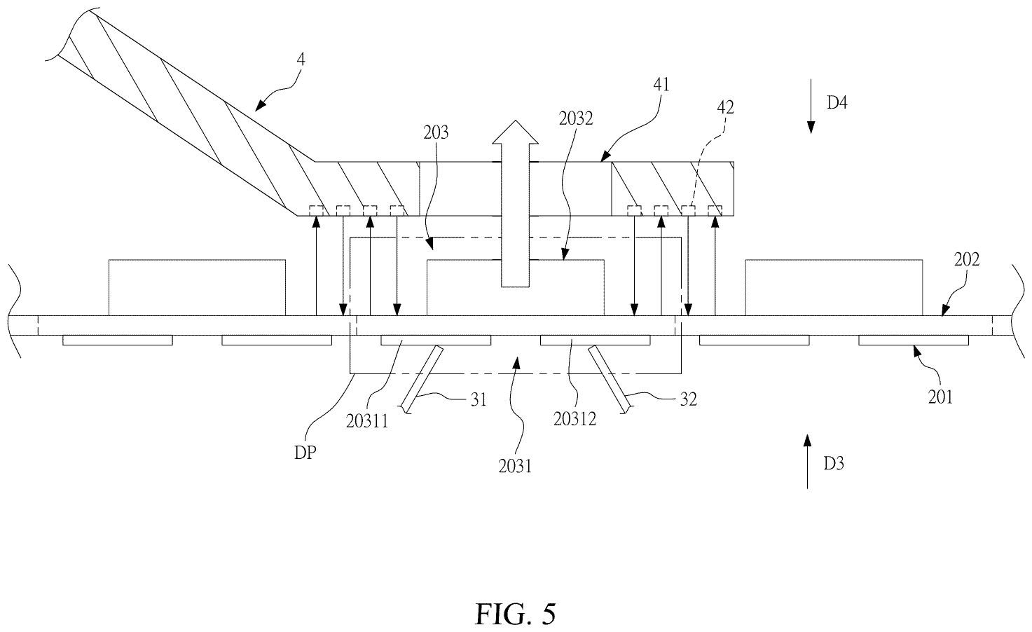

Referring now to FIG. 5, FIG. 5 is a schematic diagram of the details of the probe module and the die position holder contacting the wafer at the same time. As shown in FIG. 1 to FIG. 5, in the present embodiment, the wafer 200 having a first surface 201 and a second surface 202 opposite to the first surface 201. The wafer 200 further includes a plurality of flip chip dies 203 (only one is shown in the figure), and each of the flip chip dies 203 has an electrode portion 2031 on the first surface 201, which has two electrode contacts 20311, 20312, and has a light-emitting portion 2032 electrically connected to the two electrode contacts 20311, 20312 on the second surface 202. Specifically, the flip chip die 203 of the present embodiment is an LED flip chip die, but it is not limited thereto.

As mentioned above, in the present embodiment, the first surface 201 of the wafer 200 is facing downward and is exposed from the opening 1111, and the second surface 202 is relatively facing upward so that the probe module 3 is disposed below the wafer 200 and faces the first surface 201, and the die position holder 4 and the detection parameter acquisition module 5 are disposed above the wafer 200 and face the second surface 202. Thus, when the probe module 3 approaches the first surface 201 from the bottom of the wafer 200 along the contact direction D3, the die position holder 4 also approaches the second surface 202 of the wafer 200 along the stopping direction D4, so as to apply a holding force to the wafer 200 along the stopping direction D4, so as to keep the flip chip die 203 at a detection position DP when the probes 31, 32 of the probe module 3 contact the two electrode contacts 20311, 20312 respectively. The probe module 3, the die position holder 4 and the detection parameter acquisition module 5 of the present embodiment are preset to align with the detection position DP, and the wafer 200 is driven by the horizontal moving base 2 and the wafer fixing platform 1 so that the flip chip die 203 as a to-be-detected die moves to the detection position DP.

In actual operation, when the probes 31, 32 contact the two electrode contacts 20311, 20312 respectively, the light-emitting portion 2032 will be turned on to make it emit light. Since the die position holder 4 exposes the light-emitting portion 2032 through the through hole 41, the detection parameter acquisition module 5 can acquire the optical detection parameters of the light-emitting portion 2032 via the through hole 41.

Specifically, the die position holder 4 is a non-contact holder, and the die position holder 4 is provided with a plurality of air pressure regulating holes 42 (only one is shown in the figure) around the through hole 41. Specifically, the air pressure regulating holes 42 of the present embodiment are, for example, centered at the through hole 41, forming a four-circle annular arrangement structure from the inside to the outside, and as can be seen in FIG. 5, the air pressure provided by the air pressure regulating holes 42 from the innermost circle to the outermost circle are a staggered arrangement of positive pressure, negative pressure, and positive pressure and negative pressure, thereby effectively keeping the wafer 200 stable so that the position of the to-be-detected die of the flip chip die 203 can be kept stable. However, in other embodiments, it is not limited to this situation. The air pressure regulating holes 42 in the same circle may be arranged alternately to provide positive pressure and negative pressure. It is even possible to provide a guide member outside the air pressure regulating holes 42 so that the airflow ejected from the air pressure regulating holes 42 is guided by the guide member to form an airflow between the die position holder 4 and the wafer 200, thereby stabilizing the wafer 200 according to the Bernoulli's principle.

In addition, in other embodiments, the die position holder 4 also can be a contact holder. Specifically, when the die position holder 4 is a contact holder, the die position holder 4 directly contacts the wafer 200 to keep the wafer 200 stable, so that the position of the to-be-detected die of the flip chip die 203 is kept stable. For this, the die position holder 4 may be made of a soft material that will not damage the wafer 200.

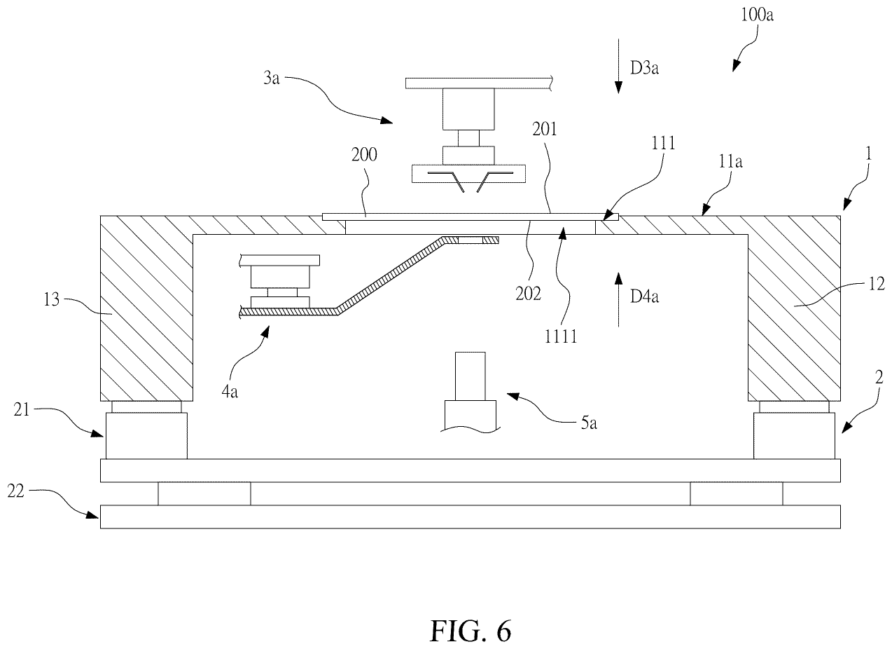

Referring now to FIG. 6, FIG. 6 is a schematic diagram showing a positioning type wafer inspection device provided by another preferred embodiment of the present invention. As shown in FIG. 1 to FIG. 6, in another embodiment, a positioning type wafer inspection device 100a also includes a wafer fixing platform 1, a horizontal moving base 2, a probe module 3a, a die position holder 4a and a detection parameter acquisition module 5a. The main difference between the positioning type wafer inspection device 100a and the aforementioned positioning type wafer inspection device 100 is: the wafer 200 is placed on the positioning structure 111 with the second surface 202 facing downward, and the second surface 202 is exposed from the opening 1111, and the probe module 3a is movably disposed on one side of the wafer 200 along a contact direction D3a, and the die position holder 4a is movably disposed on the other side of the wafer 200 along a stopping direction D4a opposite to the contact direction D3a, and the detection parameter acquisition module 5a is also disposed on the other side of the wafer 200 relative to the probe module 3a.

As mentioned above, in the present embodiment, the wafer 200 is disposed on the positioning structure 111 with the second surface 202 facing downward, and the second surface 202 is exposed from the opening 1111. Therefore, when the probe module 3a electrically contacts the two electrode contacts (not shown in the figure, which are equivalent to the two electrode contacts 20311, 20312 mentioned above) of the to-be-detected die (not shown in the figure, which is equivalent to the flip chip die 203 mentioned above) from top to bottom along the contact direction D3a, the die position holder 4a applies a holding force to the wafer 200 from bottom to top along the stopping direction D4a.

To sum up, the wafer inspection technology of the prior art uses a transparent carrier to hold the wafer. When the probe touches the wafer from the top, the signal or image generated by the die of the wafer can penetrate through the transparent carrier at the bottom, but it is also distorted due to the existence of the transparent carrier. In contrast, the present invention mainly utilizes a positioning structure with an opening to hold the wafer, and respectively provides a probe module and a die position holder on opposite sides of the wafer, so that the bottom of the wafer can be exposed from the opening, thereby allowing the probe module and the die position holder to approach the die of the wafer from both sides of the wafer. Therefore, regardless of whether the light-emitting side of the die is facing upward or downward, it can be directly received by the image acquisition device without being distorted by the interference of the transparent carrier. When the probe module contacts the wafer, the holding force applied to the wafer by the die position holder can effectively prevent the wafer from moving or deforming due to the contact of the probe module, thereby increasing the stability of the inspection.

It should be noted that since the wafer is actually a very thin structure, when the prior art uses a transparent carrier to hold the entire wafer, there is no need to worry about the wafer being deformed when the probe contacts it. However, when the present invention does not use a transparent carrier to hold the entire wafer, but uses a positioning structure to hold the periphery of the positioning wafer, the wafer can easily be deformed or shifted due to the contact of the probe module. Therefore, the present invention uses a die position holder to apply a holding force to the wafer, which can effectively improve the stability of the wafer during inspection.

While the present invention has been particularly shown and described with reference to a preferred embodiment, it will be understood by those skilled in the art that various changes in form and detail may be without departing from the spirit and scope of the present invention.

What is claimed is:

1. A positioning type wafer inspection device, for inspecting a plurality of flip chip dies on a wafer, the wafer having a first surface and a second surface opposite to the first surface, each of the flip chip dies has an electrode portion on the first surface and a light-emitting portion electrically connected to the electrode portion on the second surface, the positioning type wafer inspection device comprising:
a wafer fixing platform, having a positioning structure which has an opening, the positioning structure being used to keep the wafer within a detection position range and expose the wafer through the opening;
a horizontal moving base, used to carry the wafer fixing platform and move the wafer fixing platform on a horizontal plane to move a to-be-detected die among the flip chip dies to a detection position;
a probe module, movably disposed on one side of the wafer along a contact direction perpendicular to the horizontal plane, used to electrically contact the electrode portion of the to-be-detected die along the contact direction;
a die position holder, movably disposed on the opposite side of the wafer relative to the probe module along a stopping direction opposite to the contact direction, used to apply a holding force to the wafer along the stopping direction, thereby when probe module contacts the to-be-detected die, the to-be-detected die is kept at the detection position; and
a detection parameter acquisition module, disposed on the opposite side of the wafer relative to the probe module, used to acquire optical detection parameters from the light-emitting portion of the to-be-detected die when the probe module electrically contacts the to-be-detected die.

2. The positioning type wafer inspection device of claim 1, wherein the die position holder has a through hole, when the die position holder applies the holding force against the wafer along the stopping direction, the to-be-detected die is exposed from the through hole, so that the detection parameter acquisition module acquires optical detection parameters from the light-emitting portion of the to-be-detected die via the through hole.

3. The positioning type wafer inspection device of claim 2, wherein the die position holder is a non-contact holder, and the die position holder is provided with a plurality of air pressure regulating holes around the through hole.

4. The positioning type wafer inspection device of claim 1, wherein when the first surface of the wafer faces downward and is exposed from the opening, the probe module is disposed below the wafer, and the die position holder and the detection parameter acquisition module are disposed above the wafer.

5. The positioning type wafer inspection device of claim 1, wherein when the second surface of the wafer faces downward and is exposed from the opening, the probe module is disposed above the wafer, and the die position holder and the detection parameter acquisition module are disposed below the wafer.

6. The positioning type wafer inspection device of claim 1, wherein the wafer fixing platform includes a carrier plate and two side support seats, the carrier plate has the positioning structure, the two side support seats are respectively connected to the opposite sides of the carrier plate, and the horizontal moving base is used to hold the two side support seats.

7. The positioning type wafer inspection device of claim 6, wherein the horizontal moving base further includes a first moving component and a second moving component, the first moving component holds the two side support seats to drive the wafer fixing platform to reciprocate along a first horizontal direction, and the second moving component holds the first moving component to drive the first moving component and the wafer fixing platform to reciprocate along a second horizontal direction perpendicular to the first horizontal direction.
